(19) United States
(12) Patent Application Publication
(10) Pub. No.: US 2006/0197872 A1
(43) Pub. Date: Sep. 7, 2006

(54) Method for video signal process and method for signal processing apparatus calibration

(76) Inventors: Kuan-Yu Chen, Daliao Township (TW); Yao-Chen Huang, Taichung City (TW); Wei-Chen Shen, Hsinchu City (TW)

Correspondence Address: J.C. Patents, Inc., Suite 250, 4 Venture, Irvine, CA, 92618, US

(21) Appl. No.: 11/255,437

(22) Filed: Oct. 19, 2005

Related U.S. Application Data
(60) Provisional application No. 60/659,000, filed on Mar. 4, 2005.

(30) Foreign Application Priority Data
Jun. 20, 2005 (TW) 94120387

(51) Int. Cl. H03M 1/12

(52) U.S. Cl. 348/572; 348/682

(57) ABSTRACT

A method for processing a video signal and a method for calibrating signal processing apparatuses are disclosed. The method for video signal process comprises the following steps. First, an analog video signal having a sync pulse is provided. Then, a peak level of the sync pulse is detected, and a signal transfer gain is determined based on the peak level of the sync pulse. Finally, the analog video signal is converted into a digital signal according to the signal transfer gain.

### CROSS-REFERENCE TO RELATED APPLICATION

This application claims the priority benefits of U.S. provisional application titled “VEDIO SIGNAL AGC CALIBRATION” filed on Mar. 4, 2005, Ser. No. 60/659,000. This application also claims the priority benefit of Taiwan application serial no. 94120387, filed on Jun. 20, 2005. All disclosures of this application are incorporated herein by reference.

### BACKGROUND OF THE INVENTION

1. Field of the Invention

The present invention relates to an analog to digital converting method, and more particularly, to a method for processing a video signal.

2. Description of the Related Art

The analog-to-digital converter (abbreviated as “A/D” hereinafter) is a mandatory device in the current digital circuitry or apparatus for processing the video signals. FIG. 1 schematically shows a partial block diagram of a digital TV. Referring to FIG. 1, in a High Definition TV (HDTV), first the DC component of the signal is filtered by a DC blocking capacitor C on a signal input terminal. Then, the DC-filtered signal is transmitted to the A/D for converting the signal into a digital signal. Thereafter, the digital signal is processed by the processing unit PU and then transmitted to the display unit DU for display.

FIG. 2 schematically shows a waveform diagram of the illuminance signal (e.g. Y signal) in the HDTV video signal. The signal represents an illuminance signal on one of the scan lines. The illuminance signal further includes a sync pulse (e.g. the SP marked in the diagram). In addition, the diagram also includes a blank level BL, a white level WL and a sync level SL. Wherein, the blank level BL represents a signal level of the darkest image. The white level WL represents a signal level of the brightest image. The sync level SL represents a signal voltage level of the sync signal. In a general video signal, the voltage of the signal is counted by unit of IRE, where 140 IRE is equal to 1 Volt as shown in FIG. 2.

In general, it is common that the video signal is attenuated with different levels after it has been modulated by different modulation methods via the signal channel. The A/D is configured to provide an appropriate signal gain according to the attenuation level of the input signal so that an accurate digital signal can be converted and output. In the conventional technique, with the specific proportional ratio relationship between the level of the sync pulse in the video signal and the maximum level of the video signal, the maximum level of the image signal in the video signal may be inferred, and the amplitude of the signal gain of the A/D can be determined.

However, when the A/D is processing the video signal of FIG. 2, before the signal is sampled and converted, the back porch of the signal has to be clamped to a ground level. With such sampling method, the signal will not be sampled due to the fact that the sync pulse is out of the conversion range; thus, there is no information related to the sync pulse level in the analog-to-digital converted digital signal. Accordingly, the A/D cannot provide the appropriate signal gain according to the attenuation level of the input signal. Furthermore, the output analog-to-digital converted digital signal is not able to comply with the illuminance range defined in the specification.

### SUMMARY OF THE INVENTION

Therefore, it is an object of the present invention to provide a method for processing a video signal. With such method, the information of the sync pulse in the analog-to-digital converted digital signal is preserved, such that the A/D can determine the appropriate signal transfer gain according to the preserved information of the sync pulse and the output video signal is met with the specification requirement.

It is another object of the present invention to provide a method for calibrating the signal processing apparatus. With such method, a plurality of signal processing apparatuses is calibrated, such that the offset calibration, the gain balance, and the level restoration are accomplished.

The present invention provides a method for processing a video signal. The method for processing a video signal comprises the following steps. First, an analog video signal having at least one sync pulse is provided. Then, a peak level of the sync pulse is detected, and a signal transfer gain is determined based on the peak level of the sync pulse. Finally, the analog video signal is converted into a digital signal according to the signal transfer gain.

In the method for processing the video signal according to a preferred embodiment of the present invention, the analog video signal mentioned above comprises an illuminance (Y) signal, a Sync-on-Green signal and a Composition signal.

The present invention provides a method for calibrating a plurality of signal processing apparatuses. The method for calibrating the signal processing apparatuses comprises the following steps. First, the offset calibration is performed under the premise that it is not required to externally input the corresponding signal, such that the offset value of each signal processing apparatus is calibrated and the physical value generated according to the blank level of the analog video signal is complied with the ideal value of the video standard. Similarly, the signal transfer gain of each signal processing apparatus is calibrated under the premise that it is not required to externally input the corresponding signal, such that the physical values provided based on the same analog video signal by each of the signal processing apparatuses are matched with each other. Finally, the analog video signal is input into the corresponding signal processing apparatus respectively for performing the level restoration and tuning the signal transfer gain of each signal processing apparatus, such that the level provided by each signal processing apparatus is complied with the video standard.

In the present invention, the information related to the sync pulse level is preserved in the analog-to-digital converted digital signal, such that the A/D can determine the appropriate signal transfer gain based on the information related to the sync pulse level preserved in the analog-to-digital converted digital signal even if the information related to the sync pulse level is not preserved. Accordingly, no matter how the analog video signal is attenuated, it is still able to calibrate the signal transfer gain such that the output video signal is complied with the specification requirement.

### BRIEF DESCRIPTION DRAWINGS

The accompanying drawings are included to provide a further understanding of the invention, and are incorporated in and constitute a part of this specification. The drawings illustrate embodiments of the invention, and together with the description, serve to explain the principles of the invention.

FIG. 1 schematically shows a partial block diagram of a conventional digital TV.

FIG. 2 schematically shows a waveform diagram of an illuminance signal of a conventional HDTV.

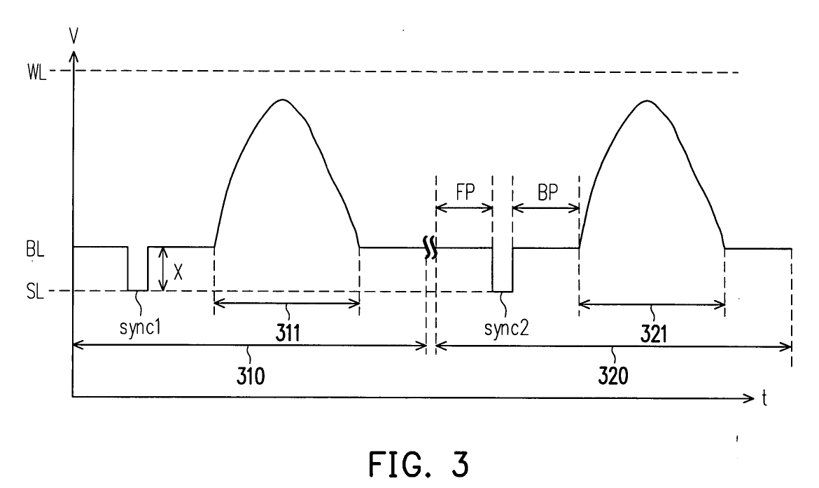

FIG. 3 schematically shows a waveform diagram of an analog video signal according to a preferred embodiment of the present invention.

FIG. 4 schematically shows a flow chart illustrating a method for processing a video signal according to a preferred embodiment of the present invention.

FIG. 5 schematically shows a waveform diagram of an illuminance (Y) video signal and the chrominance signals (Pb) and (Pr) of the analog video signal according to a preferred embodiment of the present invention.

FIG. 6 schematically shows a signal processing apparatus according to a preferred embodiment of the present invention.

FIG. 7 schematically shows a flow chart illustrating a method for calibrating a signal processing apparatus according to a preferred embodiment of the present invention.

FIG. 8A˜8D schematically show the curve diagrams illustrating the relationship between the input and the output in the method for calibrating a signal processing apparatus according to a preferred embodiment of the present invention.

### DESCRIPTION PREFERRED EMBODIMENTS

The present invention provides a method for processing a video signal having an embedded sync pulse, such as illuminance (Y) signal, Composition video signal and Sync-on-Green signal. In order to easily describe the present invention, the embodiment described below refers to an HDTV video signal that is received and converted by an analog-to-digital converter (A/D).

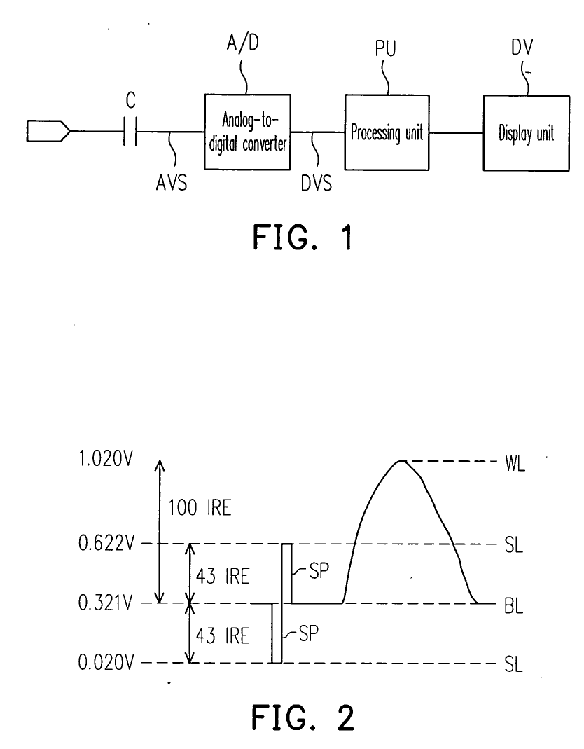

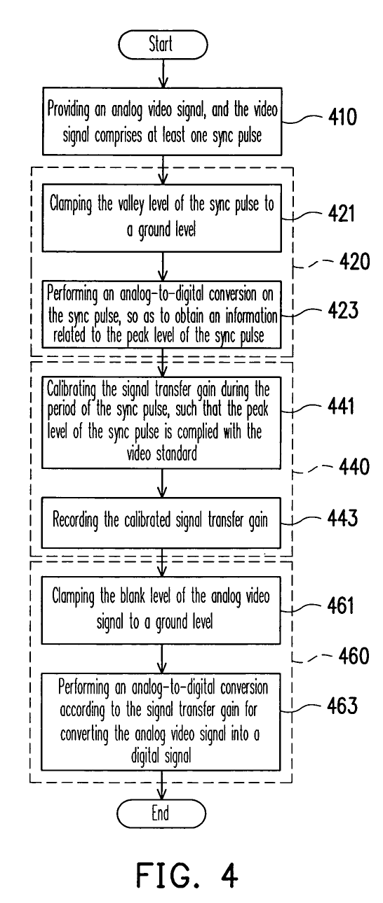

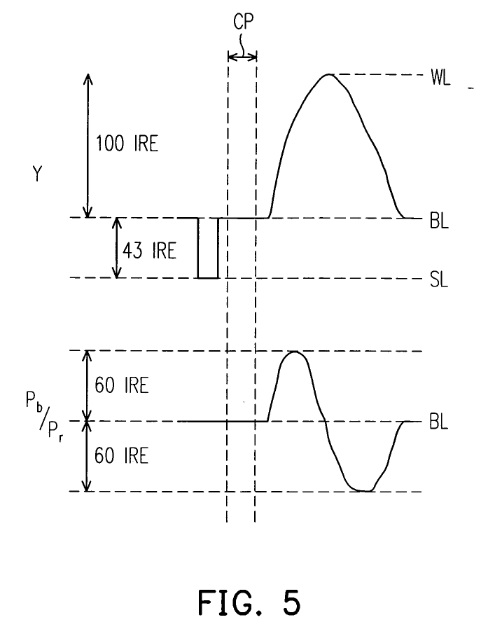

FIG. 3 schematically shows an HDTV illuminance (Y) video signal. To simplify the explanation, only the negative pulse portion of the sync pulse required in the present invention is shown in the diagram. FIG. 4 schematically shows a flow chart illustrating a method for processing a video signal according to a preferred embodiment of the present invention. Referring to FIG. 1, FIG. 3 and FIG. 4, the method for processing the video signal comprises the following steps. First, in step 410, an analog video signal AVS is provided and input into the A/D, wherein the video signal comprises at least one sync pulse (as shown in FIG. 3). Since in the HDTV signal specification, only the illuminance signal has sync pulse, the HDTV illuminance signal is exemplified herein for explanation. Then, in step 420, the peak value x of the sync pulse on one of the scan lines in the analog video signal AVS (e.g. the sync pulse sync1 of the scan line 310 in FIG. 3) is detected by the A/D.

In the present embodiment, step 420 further comprises sub-steps 421 and 423. First, the valley level SL of the sync pulse sync1 is clamped to a ground level (step 421), and then the analog-to-digital conversion is performed on the scan line 310, so as to obtain the digital data related to the peak level x of the sync pulse from the DVS, which is a digital signal provided by the A/D (step 423).

Then, in step 440, the signal transfer gain is determined according to the peak level of the sync pulse. In the present embodiment, step 440 further comprises sub-steps 441 and 443. First, the signal transfer gain is determined according to the peak level x of the sync pulse. During the transmission of the analog video signal AVS, the sync pulses (e.g. sync1 and sync2) and the image data (e.g. 311 and 312) may be attenuated due to some reason, such that the sync pulse level x cannot meet the 40 IRE requirement defined in the HDTV specification. For example, the analog video signal AVS received by the A/D is attenuated to 25% of the standard level, and the x value sampled by the A/D is equal to 30 IRE. Accordingly, the sampled 30 IRE can be used as a reference level to calibrate the signal transfer gain of the A/D during the period of the sync pulse, such that the peak level of the digital sync pulse provided by the A/D is complied with the HDTV video standard 40 IRE (step 441), and the calibrated signal transfer gain is recorded (step 443).

Then, in step 460, the analog video signal AVS is converted into the digital video signal DVS by the A/D according to the signal transfer gain. In the present embodiment, step 460 further comprises sub-steps 461 and 463. As described above, after the A/D has converted the sync pulse sync 1 of the scan line 310 and preserved the information related to the sync pulse level, the A/D further configures the clamp point of a next scan line signal (e.g. the scan line 320) on the front porch (FP) or the back porch (BP) of the analog video signal. Meanwhile, since the information related to the sync pulse level preserved previously may be used as a reference, the appropriate signal transfer gain can be determined based on the preserved information related to the sync pulse level, such that the input analog video signal AVS can be accurately converted into the digital video signal DVS. Consequently, in step 461, the blank level BL of the scan line 320 in the analog video signal AVS is clamped to the ground level by the A/D. Then, the analog video signal AVS is appropriately amplified by the A/D based on the signal transfer gain recorded in the previous step, and the analog-to-digital conversion is performed to convert the analog video signal AVS into a digital video signal DVS (step 463). Meanwhile, although there is no digital information of the sync pulse sync2 in the digital signal data DVS provided by the A/D because the sync pulse sync2 is beyond the conversion range while the A/D is converting the scan line 320, since the level x of the sync pulse sync1 had been acquired in the previous conversion of the scan line 310, the A/D is able to calibrate the signal transfer gain, such that the output analog video signal is met with the specification requirement.

In addition, the A/D sampling of the level x of the sync pulse may be completed even before the image is appeared on the screen, for example, during the period of TV power-on process, such that the image quality will not be impacted. Alternatively, the level x of the sync pulse may be sampled again during the period of switching channels.

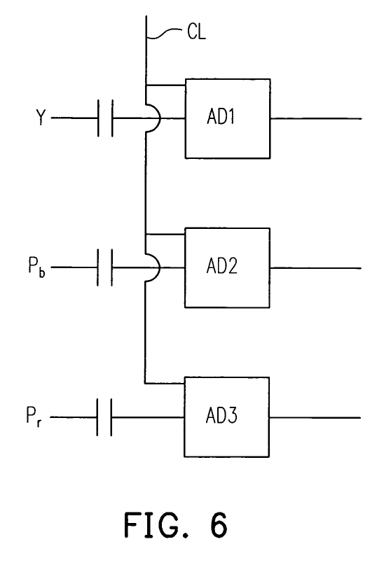

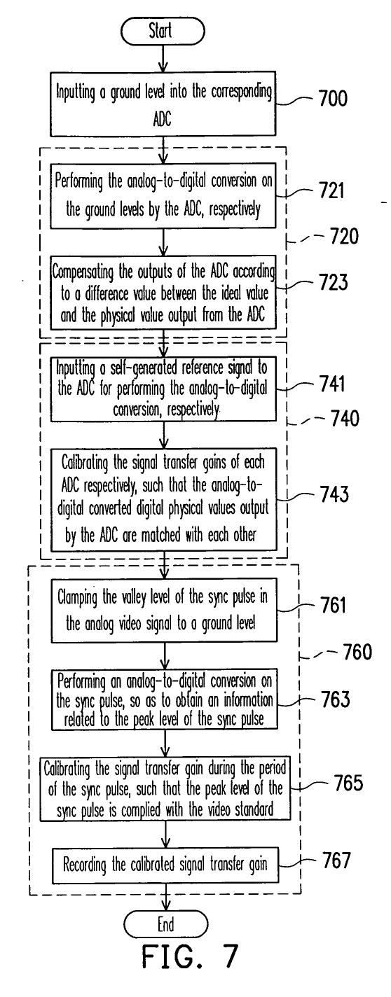

Additionally, the present invention further provides a method for calibrating the signal processing apparatus. FIG. 5 schematically shows an HDTV illuminance (Y) video signal and the chrominance signals (Pb) and (Pr). For easy explanation, the positive pulse portion of the sync pulse is not shown in the illuminance (Y) video signal of FIG. 5. FIG. 6 schematically shows a signal processing apparatus according to a preferred embodiment of the present invention. In the present embodiment, the video signal processing apparatus is an A/D, which respectively includes AD1, AD2 and AD3. In addition, three DC blocking capacitors C are further disposed on the input terminals of AD1, AD2, and AD3 respectively. Each A/D further comprises a control line CL. Referring to FIG. 5 and FIG. 6, it is assumed that each of AD1, AD2 and AD3 in the present embodiment is 8 bits. Furthermore, it is assumed that the Y signal is input into AD1, and the Pb and Pr signals are input into AD2 and AD3, respectively.

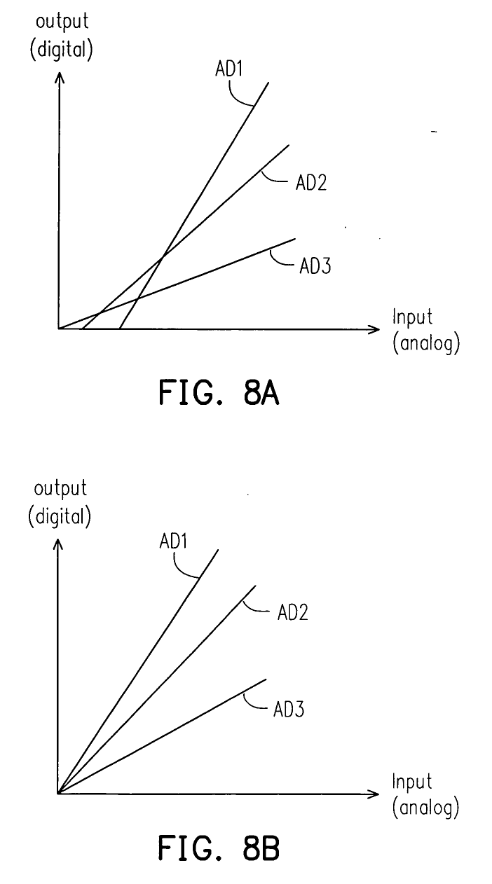

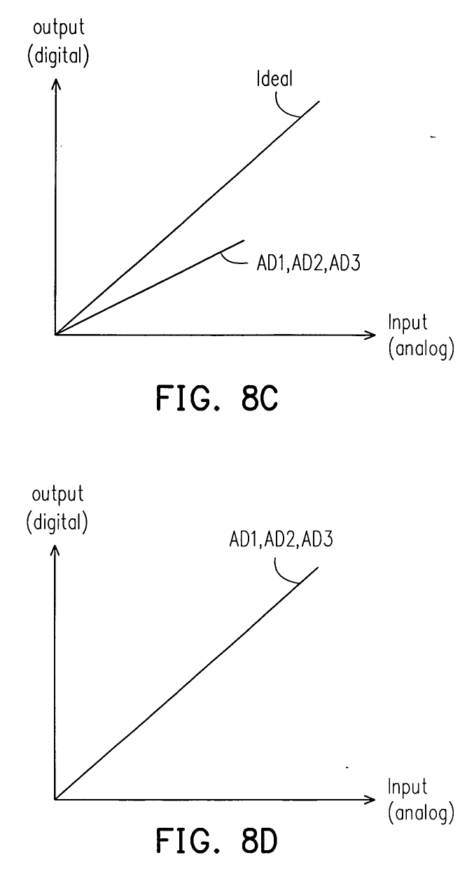

FIG. 7 schematically shows a flow chart illustrating a method for calibrating the signal processing apparatus according to a preferred embodiment of the present invention. In addition, FIG. 8A˜8D are further provided for describing the present embodiment in detail. Please refer to FIGS. 5-7 and FIGS. 8A˜8D. First, a ground level is input into the corresponding AD1, AD2 and AD3 respectively (step 700); and a calibration instruction is issued by a control line CL to indicate that the calibration is started. Since there may be some offset existed in the A/D, the output digital values may not match with each other even though the same analog signals are input (as shown in FIG. 8A). Thus, the offset calibration is next performed to calibrate the offset of the A/D, such that the physical value generated according to the blank level of the analog video signal is complied with the ideal value of the video standard (step 720). In the present embodiment, step 720 further comprises sub-steps 721 and 723. First, the analog-to-digital conversion is performed on the ground level of the signal processing apparatus by AD1, AD2 and AD3, respectively (step 721). Then, in step 723, the outputs of the A/D are compensated based on a difference value between the ideal value and the physical values provided by the AD1, AD2 and AD3, respectively. For example, when the blank level BL of the Y signal is input into AD1, ideally AD1 should output a value of 0. If the physical output of the AD1 is 3, it indicates that the offset of AD1 is 3. In such case, a value of 3 has to be subtracted from the output of AD1 in order to compensate AD1. In another example, when the blank level BL of the Pb signal is input into AD2, ideally AD2 should output a value of 128. If the physical output of AD2 is 120, a value of 8 has to be added to the output of AD2 in order to compensate AD2. FIG. 8B schematically show a curve diagram illustrating the relationship between the input and the output of AD1, AD2 and AD3 after step 720 is completed.

Then, the gain balance is performed to calibrate the signal transfer gain of the A/D, such that the physical values generated by the signal processing apparatus based on the same analog video signal are matched with each other (step 740). In the present embodiment, step 740 further comprises sub-steps 741 and 743. First, a self-generated reference signal is input into AD1, AD2 and AD3, respectively, and an analog-to-digital conversion is performed (step 741). Then, the signal transfer gains of AD1, AD2, and AD3 are respectively calibrated, such that the digital physical values provided by the AD1, AD2 and AD3 are matched with each other (step 743). FIG. 8C schematically shows a curve diagram illustrating the relationship between the input and the output of the AD1, AD2, and AD3 after step 740 is completed. As shown in FIG. 8C, although the slopes of AD1, AD2 and AD3 (i.e. the respective signal transfer gain of AD1, AD2, and AD3) are matched with each other, they are not complied with the HDTV standard yet (i.e. the curve Ideal shown in FIG. 8C).

Therefore, the level restoration is performed subsequently to calibrate the signal transfer gain of the A/D, such that the output level of the A/D is complied with the video standard (step 760). In the present embodiment, step 760 further comprises sub-steps 761, 763, 765, and 767. First, the valley level of the sync pulse on one of the scan lines of the analog video signal Y is clamped to the ground level by AD1 (step 761); and the analog-to-digital conversion is performed based on the sync pulse level, so as to obtain the digital information related to the peak level x of the sync pulse (step 763). Then, the signal transfer gain of AD1, AD2, and AD3 are calibrated based on the digital peak level x at the same time, such that the peak level x of the sync pulse is complied with the HDTV video standard 40 IRE (step 765); and the calibrated signal transfer gain is recorded (step 767). FIG. 8D indicates a fact that the curve illustrating the relationship between the input and the output of AD1, AD2 and AD3 after the step 760 is completed, which proves that the HDTV standard is achieved.

In summary, in the present invention, the information related to the sync pulse level is preserved in the analog-to-digital converted digital signal, such that the A/D can determine the appropriate signal transfer gain based on the information related to the sync pulse level preserved in the analog-to-digital converted digital signal even if the information related to the sync pulse level is not preserved. Accordingly, regardless how the analog video signal is attenuated, it is still able to calibrate the signal transfer gain, such that the output video signal is complied with the specification requirement.

Although the invention has been described with reference to a particular embodiment thereof, it will be apparent to one of the ordinary skill in the art that modifications to the described embodiment may be made without departing from the spirit of the invention. Accordingly, the scope of the invention will be defined by the attached claims not by the above detailed description.

What is claimed is:

1. A method for processing a video signal, comprising:
providing an analog video signal including at least one sync pulse;
detecting a peak level of the sync pulse;
determining a signal transfer gain according to the peak level of the sync pulse; and
converting the analog video signal into a digital video signal according to the signal transfer gain.

2. The method for processing the video signal of claim 1, wherein the analog video signal is an illuminance (Y) signal.

3. The method for processing the video signal of claim 1, wherein the analog video signal is a Sync-on-Green signal.

4. The method for processing the video signal of claim 1, wherein the analog video signal is a Composite signal.

5. The method for processing the video signal of claim 1, wherein the steps of detecting the peak level of the sync pulse comprise:
clamping a valley level of the sync pulse to a ground level; and
performing an analog-to-digital conversion on the sync pulse so as to obtain information related to the peak level of the sync pulse.

6. The method for processing the video signal of claim 5, wherein the steps of determining the signal transfer gain according to the peak level of the sync pulse comprise:
calibrating the signal transfer gain during a period of the sync pulse, such that the peak level of the sync pulse is complied with a video standard; and
recording the calibrated signal transfer gain.

7. The method for processing the video signal of claim 6, wherein the video standard is an HDTV standard.

8. The method for processing the video signal of claim 1, wherein the steps of converting the analog video signal into the digital signal according to the signal transfer gain comprise:
clamping a blank level of the analog video signal to a ground level; and
performing an analog-to-digital conversion according to the signal transfer gain for converting the analog video signal into the digital video signal.

9. A method for calibrating a plurality of signal processing apparatuses, and the method for calibrating the signal processing apparatuses comprising:
performing an offset calibration under a premise of not requiring to externally input a corresponding signal to calibrate an offset value of the signal processing apparatuses, such that a physical value output according to a blank level of an analog video signal is complied with an ideal value of a video standard; and
performing a gain balance under a premise of not requiring to externally input a corresponding signal to calibrate the signal transfer gain of each of the signal processing apparatuses, such that the physical values provided by each of the signal processing apparatuses according to the analog video signal are matched with each other.

10. The method for calibrating the signal processing apparatuses of claim 9, further comprising:
performing a level restoration to calibrate the signal transfer gain of the signal processing apparatuses, such that the output levels of the signal processing apparatuses are complied with the video standard.

11. The method for calibrating the signal processing apparatuses of claim 10, wherein the signal processing apparatuses are analog-to-digital converters.

12. The method for calibrating the signal processing apparatuses of claim 10, wherein the offset calibration comprises:
performing an analog-to-digital conversion on the ground levels of the signal processing apparatuses by the signal processing apparatuses, respectively; and
compensating the outputs of the signal processing apparatuses according to a difference value between the ideal value and the physical value provided by the signal processing apparatuses.

13. The method for calibrating the signal processing apparatuses of claim 9, wherein the gain balance comprises:
performing an analog-to-digital conversion on a self-generated voltage level by the signal processing apparatuses, respectively; and
calibrating the signal transfer gains of each of the signal processing apparatuses respectively, such that the analog-to-digital converted digital physical values provided by each of these two signal processing apparatuses are matched with each other.

14. The method for calibrating the signal processing apparatuses of claim 10, wherein the analog video signal comprises at least one sync pulse, and the level restoration comprises:
detecting a peak value of the sync pulse by the signal processing apparatuses;
determining the respective signal transfer gain according to the peak level of the sync pulse by each of the signal processing apparatuses; and
converting the analog video signal into the digital video signal according to the signal transfer gain by the signal processing apparatus, respectively.

15. The method for calibrating the signal processing apparatus of claim 14, wherein the steps of detecting the peak level of the sync pulse comprise:
clamping a valley level of the sync pulse to a ground level; and
performing an analog-to-digital conversion on the sync pulse so as to obtain information related to the peak level of the sync pulse.

16. The method for calibrating the signal processing apparatus of claim 15, wherein the steps of determining the signal transfer gain according to the peak level of the sync pulse comprise:
calibrating the signal transfer gain during a period of the sync pulse, such that the peak level of the sync pulse is complied with a video standard; and
recording the calibrated signal transfer gain.

17. The method for calibrating the signal processing apparatus of claim 14, wherein the steps of converting the analog video signal into the digital signal according to the signal transfer gain comprise:
clamping a blank level of the analog video signal to a ground level; and
performing an analog-to-digital conversion according to the signal transfer gain for converting the analog video signal into the digital signal.

18. The method for calibrating the signal processing apparatuses of claim 9, wherein the video standard is an HDTV standard.

19. The method for calibrating the signal processing apparatuses of claim 18, wherein when the video signal is an illuminance signal, the ideal value is 0.

20. The method for calibrating the signal processing apparatus of claim 18, wherein when the video signal is a chrominance signal, the ideal value is a medium value.
